(19) United States
(12) Patent Application Publication
(10) Pub. No.: US 2010/0264426 A1
(43) Pub. Date: Oct. 21, 2010

(54) DIAMOND CAPACITOR BATTERY

(76) Inventor: Christopher Blair, San Jose, CA (US)

Correspondence Address: Trellis Intellectual Property Law Group, PC, 1900 EMBARCADERO ROAD, SUITE 109, PALO ALTO, CA, 94303, US

(21) Appl. No.: 12/427,390

(22) Filed: Apr. 21, 2009

(51) Int. Cl. H01L 29/16; H01L 21/04

(52) U.S. Cl. 257/77; 438/105; 257/E29.082; 257/E21.042

(57) ABSTRACT

In one embodiment, a charge storage device can include: a first node having a plurality of n-type diamond layers connected together; and a second node having a plurality of p-type diamond layers connected together, the plurality of p-type diamond layers being interleaved with the plurality of n-type diamond layers, where each of the plurality of diamond layers is formed using chemical vapor deposition (CVD).

### TECHNICAL FIELD

The present disclosure relates generally to semiconductors, and more specifically to energy storage and diode semiconductor devices.

### BACKGROUND

Silicon is typically used to make semiconductor devices by doping with excess electrons (n-type) or holes (p-type). Diodes are semiconductor devices made by forming a junction between p-type and n-type materials. Such devices are bipolar, and can be forward or reverse biased by applying a voltage across the junction.

Capacitors are traditionally made with conductive plates separated by a dielectric material, such as silicon dioxide. These plates act as a positive node (anode) and a negative note (cathode). The plates can also be arranged in an alternating “stacked” configuration to boost the capacitance of the capacitor. Capacitance is also created by a diode p-n junction when the diode is biased, and a depletion region develops over the border between the n-type and p-type doped materials of a junction diode. The width of the depletion region is adjustable by application of a variable reverse-biased voltage across the diode terminals. The depletion region width determines a capacitance across the diode.

### BRIEF DESCRIPTION OF THE DRAWINGS

FIGS. 1A-1C illustrate example capacitor and diode structures.

FIG. 2 illustrates a flow diagram of an example method of making a stacked sandwich capacitor using diamond components.

FIGS. 3A-3W illustrate example process steps for making a stacked sandwich capacitor using diamond components.

FIG. 4 illustrates an example stacked sandwich capacitor formed with diamond components.

FIG. 5 is a cross-sectional diagram illustrating an example diamond crystal structure.

FIG. 6 illustrates an example p-n junction using p-doped and n-doped diamond.

FIG. 7 illustrates an example p-n junction on a non-planar surface.

FIG. 8 illustrates an example of multiple diamond p-n junctions on an uneven/sloping surface.

FIG. 9 illustrates an example of connection busses to bond n-layers and p-layers together.

FIGS. 10A-10B illustrate example non-planar diamond crystalline structures.

FIG. 11 illustrates an example concentric cylinder application of doped diamond.

FIG. 12 illustrates an example construction of stacked layers in a diamond cylindrical stack structure.

FIG. 13 illustrates an example gem shape p-n diamond structure.

FIG. 14 illustrates an example prismatic shape p-n diamond structure.

FIG. 15 illustrates an example cylinder shape p-n-diamond structure.

### DETAILED DESCRIPTION OF EMBODIMENTS

### Overview

In one embodiment, a charge storage device can include: a first node having a plurality of n-type diamond layers connected together; and a second node having a plurality of p-type diamond layers connected together, the plurality of p-type diamond layers being interleaved with the plurality of n-type diamond layers, where each of the plurality of diamond layers is formed using chemical vapor deposition (CVD).

In one embodiment, a method of forming a charge storage device can include: forming a first node portion from n-type diamond material using CVD; forming a second node portion from p-type diamond material using CVD; and repeating the forming the first node portion and the forming the second node portion for each of a plurality of layers, wherein the plurality of layers are interleaved between the p-type and n-type diamond material.

In one embodiment, an apparatus can include: an n-type diamond layer having a plurality of n-doped carbon atoms; a p-type diamond layer having a plurality of p-doped carbon atoms, where each layer has a thickness in a range of from about an atom spacing to greater than about 1 nm; an n-lead coupled to the n-type diamond layer, and where each of the diamond layers is formed using CVD; and a p-lead coupled to the p-type diamond layer, where the layers conform to a predetermined shape.

### EXAMPLE EMBODIMENTS

Particular embodiments include a capacitor or diode formed of layered diamond, with layers alternatively doped n-type and p-type. In some cases, one or more of the layers may be non-doped or intrinsic, and maybe used to form a capacitor structure. For example, a non-doped intrinsic crystalline diamond layer may be used as a dielectric between alternatively doped n-type and p-type layers. Thus, particular embodiments include: (i) the formation of junction diode/capacitor devices having n-doped and p-doped interleaved diamond layers; and/or (ii) the formation of capacitor structures having interleaved n-doped diamond, dielectric, and p-doped layers.

The diamond can be assembled in multiple layers by any suitable processing technique, such as chemical vapor deposition (CVD). For example, a form of carbon can be used as a feedstock in a CVD process for application of diamond layers. The CVD allows atoms to achieve an appropriate arrangement for crystalline pattern formation. Resultant structures as described herein can include a capacitor for electrostatic energy storage, a diode (e.g., a light-emitting diode (LED)), a battery, etc., and may be suitable for use in various electronic products.

Particular embodiments can include diamond portions layered in a “sandwich” or “stacked sandwich” configuration so as to afford as large a p-n junction as possible. The capacitance associated with such a p-n junction when the junction is biased (either forward or reversed) results in a repository for electrostatic charge. Further, this capacitance is variable (e.g., when in a variable capacitor or varactor diode configuration) due to biasing that affects depletion region length or distance.

For example, in sandwich parallel plate capacitor configurations with dielectrics, capacitance may be determined as shown below in Equation 1:

C=εₖA/d=κₑε₀A/d (1)

In Equation 1, C=capacitance, A=cross-sectional area of the capacitor, d=distance across the dielectric, ε₀=the permittivity of free space=8.85×10⁻¹² F/m, εₖ=the permittivity of the dielectric, and κₑ=the dielectric constant of the dielectric.

In order to make capacitors with smaller dimensions and higher capacitances using the same or similar materials, e.g., anodes and cathodes may be “stacked” to form a “sandwich” capacitors structure, thereby increasing an effective area (A) and raising an overall capacitance value. Of course, other suitable structures, some examples of which will be discussed below, can also be supported in particular embodiments.

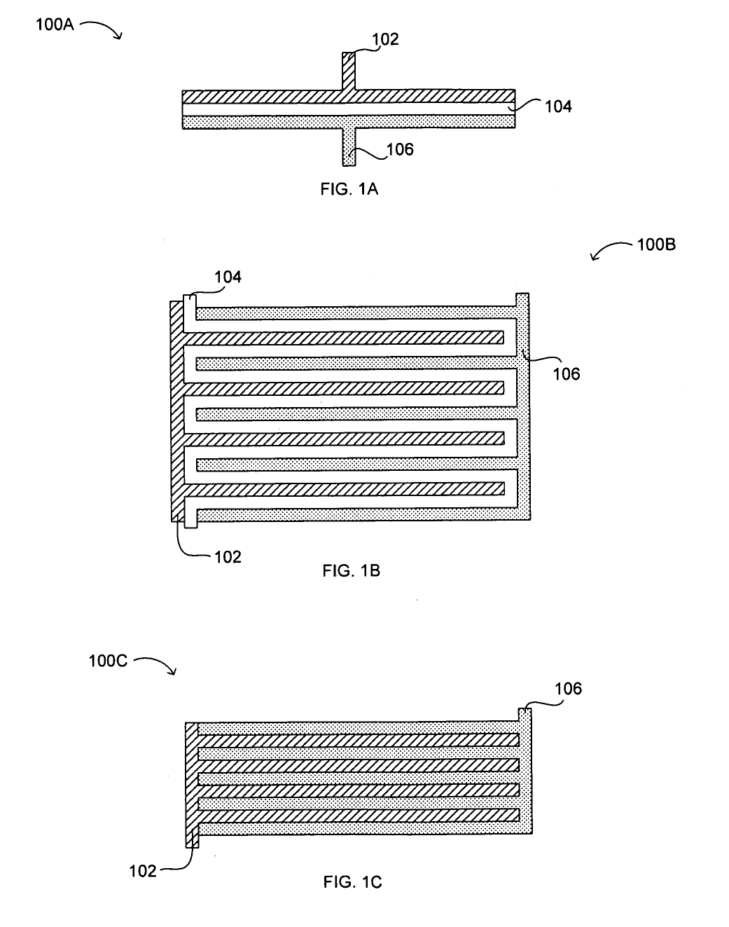

Referring now to FIGS. 1A-1B, shown are example capacitor structures having dielectrics. In FIG. 1A, capacitor 100A is formed with first node (e.g., anode) 102 separated from second node (e.g., cathode) 106 by dielectric 104. In FIG. 1B, capacitor 100B is a stacked sandwich capacitor structure, which effectively multiplies effective area A by a number of plates on each side, while holding all other variables relatively constant. However, some such stacked sandwich capacitors have limitations in thicknesses of sandwich plates, and therefore the number of such plates that can be effectively stacked. Most of these constraints come from the durability (or lack thereof) of the materials used for anode 102, cathode 106, and dielectric 104.

FIG. 1C shows an example diode/capacitor structure without a dielectric. In this case, first node 102 may be interleaved with second node 106 without a dielectric therebetween. Thus, a varactor type of capacitor, or a diode, can be formed in particular embodiments.

Layer thicknesses in particular embodiments can range from as low as an atom spacing, as well as from about 0.3 nm to about 3 nm, such as from about 0.75 nm to about 1.5 nm, and including about 1 nm. Further, different structures, such as prismatic shapes, cylinders, queues, etc. can be formed by combining any number of layers or slices as described herein. For example, 70 million layers can be used to form an object with a length of about 7 cm, but any number of layers can be employed in particular embodiments.

Chemical vapor deposition (CVD) can be used for deposition of very thin wafers of diamond-crystal carbon. In addition, by doping with, e.g., boron (B) or phosphorus (P), both positive (p-type) and negative (n-type) semiconductor materials can be developed. For example, using pure or intrinsic diamond crystal as a dielectric layer, and p-type and n-type doped diamond crystal as anode and cathode terminals, sandwich capacitor structures can be formed. In addition, any other suitable dopants, such as nitrogen for n-type dopants, can be used in particular embodiments.

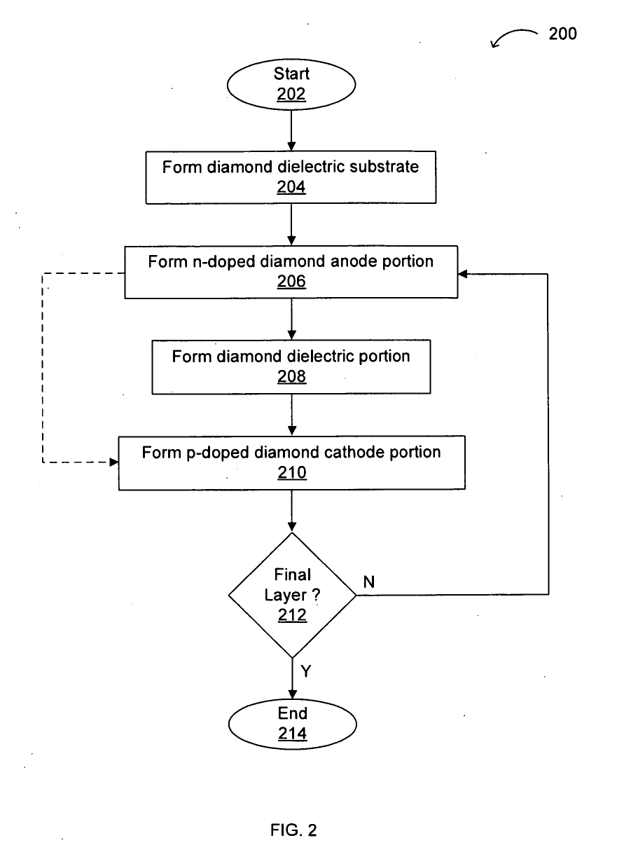

Referring now to FIG. 2, shown is a flow diagram 200 of an example method of making a stacked sandwich capacitor using diamond components. The flow begins (202), and a diamond dielectric substrate can be formed (204). An anode portion can be formed from n-doped diamond material (206). A diamond dielectric portion can then be formed, such as using pure diamond crystal (208). Next, a cathode portion can be formed from p-doped diamond material (210).

Alternatively, n-doped anode and p-doped cathode portions can be placed in contact with each other, and without an intervening dielectric layer. Such a structure forms a p-n junction that may function as a diode, or a capacitor with varying capacitance values across a depletion layer at the junction, and based on an applied bias across the anode and cathode terminals. The process of steps 206, 210, and alternately 208, can be repeated until a final layer (212) of the stacked sandwich capacitor structure is formed, thus completing the flow (214).

CVD of diamond can be used to produce cultured diamond by creating an atmosphere for carbon atoms in a gas to settle on a substrate in crystalline form. CVD diamond growth can occur under low pressure (e.g., 1-27 kPa; 0.145-3.926 psi; 7.5-203 Torr), and may involve feeding varying amounts of gases into a chamber, energizing them and providing conditions for diamond growth on the substrate. These gases include a carbon source, and may include hydrogen as well. Energy sources include hot filament, microwave power, and arc discharges, among others. The energy source can be used to generate a plasma in which the chamber gases are broken down such that complex chemistries occur.

Such CVD diamond growth can allow growth of diamond over large areas, growth of diamond on a substrate, and control over properties of the diamond produced. Growing diamond directly on a substrate allows addition of many of diamond's important qualities to other materials. For example, because diamond has the highest thermal conductivity of any material, layering diamond onto high heat producing electronics (e.g., optics, transistors, etc.) allows the diamond to be used as a heat sink. Characteristics of diamond include very high scratch resistance and thermal conductivity, combined with a lower coefficient of thermal expansion than, e.g., Pyrex glass, a coefficient of friction close to that of, e.g., Teflon (Polytetrafluoroethylene), and strong lipophilicity.

In addition, CVD diamond growth affords control of properties of the diamond produced. As used in the area of diamond growth, “diamond” can include any material having suitably bonded carbon atoms. By regulating the processing parameters (e.g., the gases introduced, pressure the system is operating under, temperature of the diamond, method of generating plasma, etc.), many different “diamond” or diamond like materials. Further, single crystal diamond can be made containing various dopants, and polycrystalline diamond having grain sizes from under about 1 nm (e.g., an atom spacing, spacing of a few atoms, etc.) to about several micrometers can be grown.

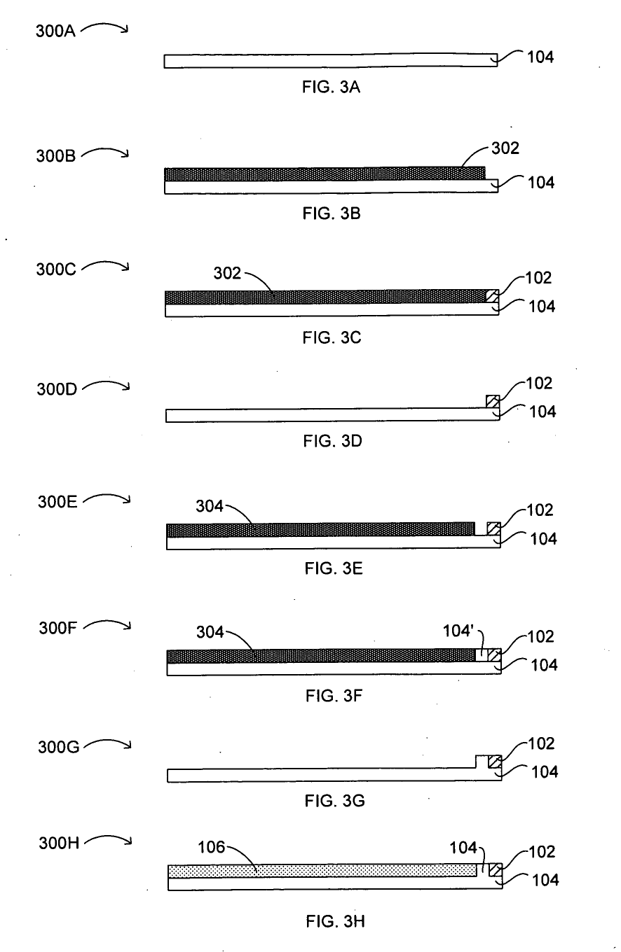

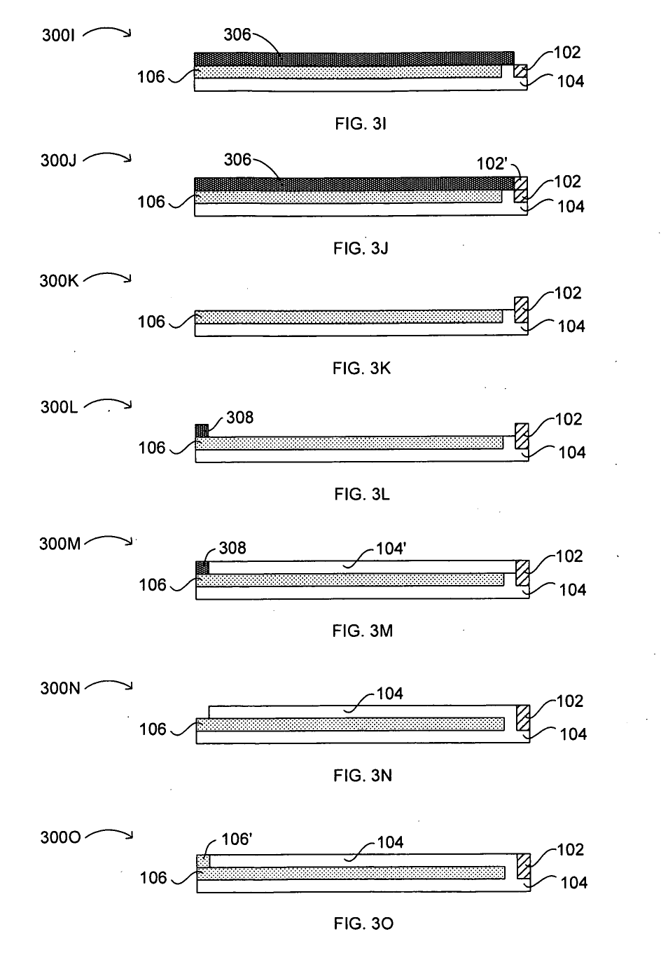

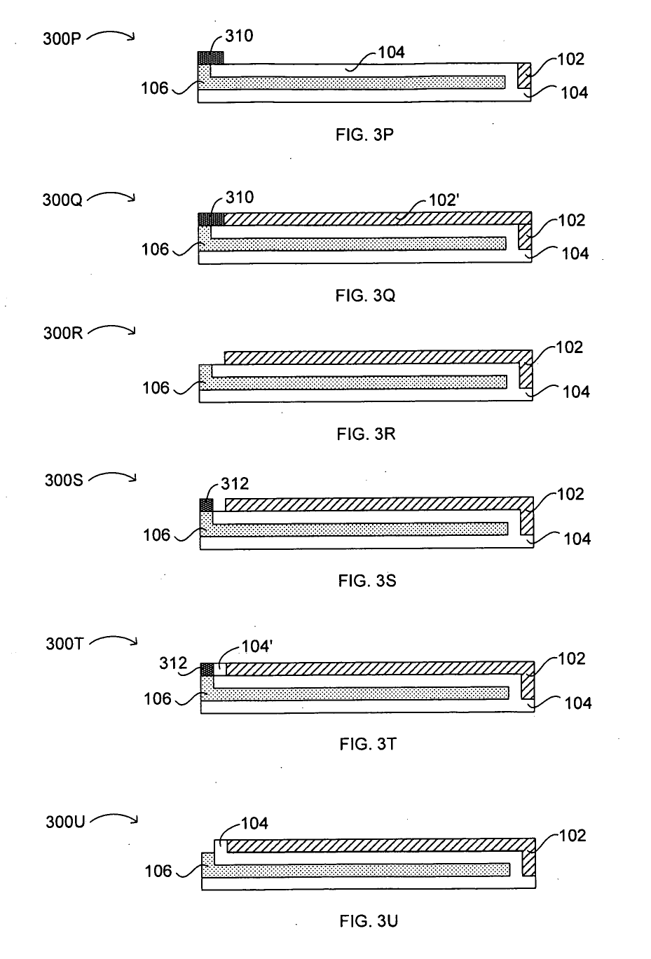

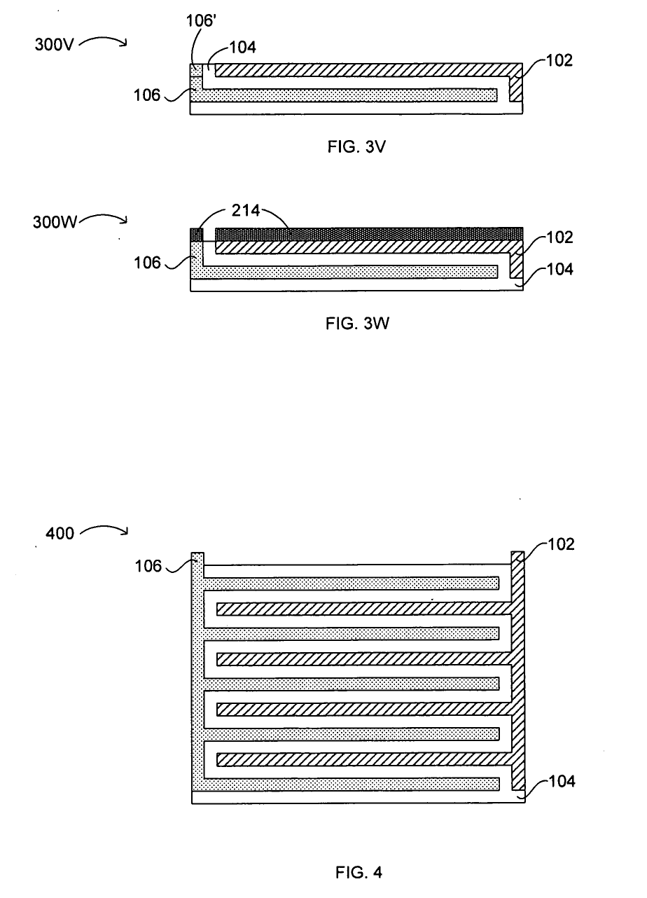

Referring now to FIGS. 3A-3W, shown are example process steps for making a stacked sandwich capacitor using diamond components. In FIG. 3A (300A), a dielectric substrate 104 can be formed. For example, pure crystalline diamond material can be used for the dielectric substrate 104. As discussed above, example thicknesses of layer 104 can range from about 0.75 nm to about 1.5 nm, such as about 1 nm.

In FIG. 3B (300B), a masking layer 302 can be added to define an anode portion. For example, photolithography can be used to expose portions of an applied masking material to form defined masking layer 302. In FIG. 3C (300C), an anode portion 102 can be deposited in the regions defined by masking layer 302. In FIG. 3D (300D), masking layer 302 can be removed.

In FIG. 3E (300E), masking layer 304 can be added to define a dielectric portion. In FIG. 3F (300F), dielectric portion 104′ can be added to connect with previous dielectric portion 104. In FIG. 3G (300G), masking layer 304 can be removed. In FIG. 3H (300H), cathode portion 106 can be added. For example, and as discussed above cathode portion 106 may have a thickness in any suitable range, including as low as an atom spacing, as well as from about 0.75 nm to about 1.5 nm, or thicker, and including about 1.0 nm.

In FIG. 3I (300I), masking layer 306 can be applied to cover cathode layer 106 and extended dielectric portion 104. In FIG. 3J (300J), an extended anode portion 102′ can be added to connect to previous anode portion 102. In FIG. 3K (300K), masking layer 306 can be removed. In FIG. 3L (300L), masking layer 308 can be added to define another dielectric portion. In FIG. 3M (300M), dielectric portion 104′ can be added to connect with previous dielectric portion 104.

In FIG. 3N (300N), masking layer 308 can be removed. In FIG. 3O (300O), cathode portion 106′ can be added to connect with previous cathode portion 106, as shown. In FIG. 3P (300P), masking layer 310 can be added to define an additional anode portion. In FIG. 3Q (300Q), anode portion 102′ can be added to connect to previous anode portion 102, as shown. In FIG. 3R (300R), masking layer 310 can be removed to reveal anode portion 102. For example, and as discussed above, anode portion 102 may have a thickness in any suitable range, such as from about 0.75 nm to about 1.5 nm, and including about 1.0 nm.

In FIG. 3S (300S), masking layer 312 can be added to define an area for additional dielectric material. In FIG. 3T (300T), dielectric portion 104′ can be added to connect to previous dielectric portion 104. In FIG. 3U (300U), masking layer 312 can be removed. In FIG. 3V (300V), additional cathode layer material can be added (106′) as shown. In FIG. 3W (300W), masking layer 214 can be added for subsequent anode/cathode/dielectric formation.

Referring now to FIG. 4, shown is an example stacked sandwich capacitor 400 with diamond components. In this particular example, four anode 102 extensions are sandwiched with five cathode 106 extensions, separated by dielectric 104. As discussed above, dielectric 104 may be removed from the process such that direct p-n junctions can be formed using doped diamond material. Further, any suitable number of extensions or stacking layers of anodes/cathodes (e.g., 4, 5, 6, 7, etc.) can be utilized in particular embodiments.

When such a stacked p-n-neutral junction structure is formed as described herein, a semiconducting capacitor with relatively good thermal and electrical properties can be achieved. For example, by using diamond materials, an electrostatic energy storage device is limited by the dielectric strength or breakdown voltage E=2×10⁹ V/m for diamond (about the highest known for any material), giving a maximum electric storage density of 1.0×10⁸ J/m³.

In one parallel plate example, a layer thickness (e.g., anode, cathode, dielectric) can be about 50 μm. If roughly the dimensions of a car battery (e.g., about 8″×8″×12″), and since two of every four “slices” is dielectric material, and one of every four is p-doped, and one of every four is n-doped, that means one “segment” of the battery is about 200 μm, and the cross-sectional area is 2×8″×12″=192 in.² In a battery that is 8 inches tall, about 8″/200 μm, or about 200 k, segments are contained therein. The capacitance for one such segment is given as shown below in Equation 2.

C=εₖA/d=(5.04×10⁻¹¹ F/m)×(0.124 m²)÷(5×10⁻⁵ m). (2)

Thus, C=1.25×10⁻⁷ F, or 125 nF. The electric field in the segment when charged to 24 VDC=24 V/50 μm=480,000 V/m. The energy in one segment at 24 VDC=½ CV²=½ (1.25×10⁻⁷)(24)²=3.6×10⁻⁵ J.

Diamond also has mechanical properties that make it feasible to create many ultra-thin layers, and still have a robust product. For example, LEDs, as well as usage in watches and jewelry and so forth, can be formed in particular embodiments. In addition, “energy storage” applications can include batteries for cell phones, cameras, cars, pacemakers, diesel electric locomotives, power plants, and so on. Thus, particular embodiments are suitable for a very wide range of applications and sizes of storage devices. For example, particular embodiments can be used to form energy storage devices with substantially long lives, making them useful for pacemakers, etc., as well as other battery applications. For jewelry applications, a gem could essentially be the battery itself. In LED and battery applications, a gem-like LED can “twinkle.”

When making electrostatic storage devices from diamond via a CVD process, the maximum field strength (and consequently, breakdown voltage) can be made large enough for any potential application. To accomplish this, the “sandwich” or interleaved layer approach with doped diamond, pure diamond, and/or reverse-biasing the capacitor or diode-capacitor (resulting in a “zener effect” if reverse-biased), can be used.

The maximum field that could be stored in a capacitor may be determined by the dielectric strength or breakdown voltage (e.g., E=2×10⁹ V/m for diamond, which is about the highest known for any material), giving a maximum electric storage density of 1.0×10⁸ joules/m³. However, reverse-biased doped diamond (p/n) junction and “sandwich” materials (e.g., p-neutral-n) may yield much higher breakdown voltages. In maximizing both the dielectric coefficient and the breakdown voltage to achieve maximum possible energy density (joules/cm³), various sandwich combinations (e.g., p-n-p-n- . . . , or p-neut-n-neut-p, or p-neut-p-neut- . . . , or n-neut-n-neut- . . . , etc.) as well as the source voltage polarity, can be accommodated.

Although particular example structures described herein show a simple p-n-p-n- . . . and a simple p-neut-n-neut-p- . . . configuration, any other suitable configuration or permutation can be utilized in particular embodiments. These various configurations represent example interleaved layer variations in accordance with certain embodiments. Table 1 below shows various examples of such interleaving variations, where “p”=positively doped carbon, “n”=negatively doped carbon, and “neut”=non-doped carbon).

TABLE 1

p-n-p-n-p-n-p-n-etc.
n-neut-n-neut-n-neut-etc.
p-neut-p-neut-p-neut-etc.
p-n-p-neut-p-n-p-neut-p-n-p-neut-etc.
n-p-n-neut-n-p-n-neut-n-p-n-neut-etc.
p-neut-n-neut-p-neut-n-neut-etc.
p-n-neut-p-n-neut-p-n-neut-etc.

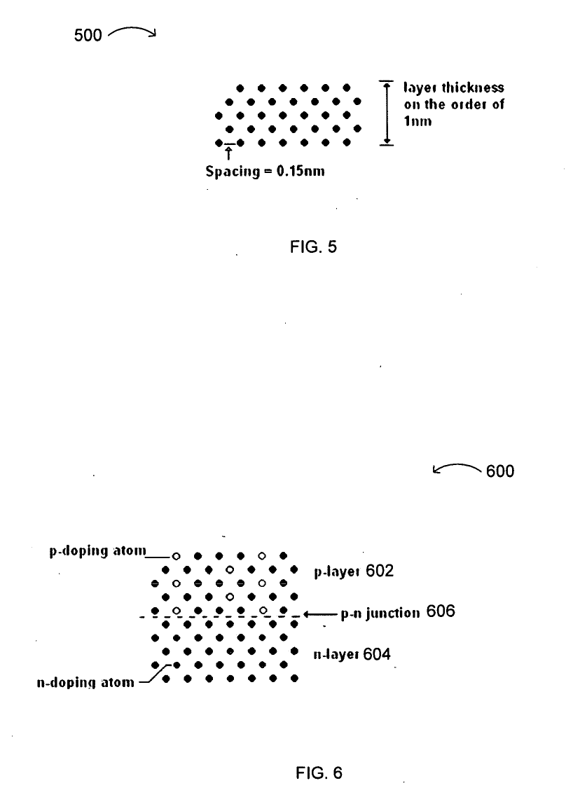

Referring now to FIG. 5, shown is a cross-sectional diagram 500 illustrating an example diamond crystal structure. For example, each dot represents an individual carbon atom, where the spacing between these items can be about 0.15 nm, and a layer thickness can be about 1 nm. As discussed above, such a layer of diamond may be laid down using a CVD process.

Referring now to FIG. 6, shown is an example p-n junction 600 using p-doped and n-doped diamond. In this example, p-layer 602 can meet n-layer 604 to form p-n junction 606. A CVD process can also be used here to lay down p-doped and n-doped regions as shown.

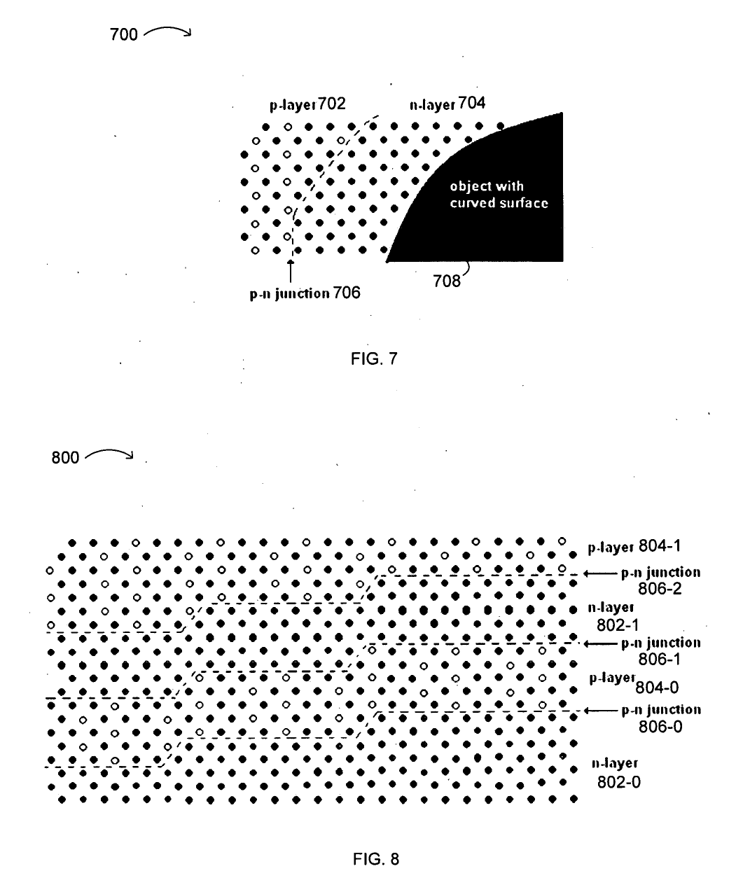

Referring now to FIG. 7, shown is an example 700 p-n junction on a non-planar surface. In this example, p-layer 702 meets n-layer 704 to form p-n junction 706, which may conform to an underlying object having a curved surface (e.g., 708). A CVD process can be used to conform p-n junction 706 to a shape of object 708.

Referring now to FIG. 8, shown is an example 800 of multiple or “stacked” diamond p-n junctions on an uneven/sloping surface. In this fashion, non-planar layers of doped diamond can be constructed to form any number of p-n junctions. For example, n-layer 802-0 and p-layer 804-0 can form p-n junction 806-0, p-layer 804-0 and n-layer 802-1 can form p-n junction 806-1, n-layer 802-1 and p-layer 804-1 can form p-n junction 806-2, and so on.

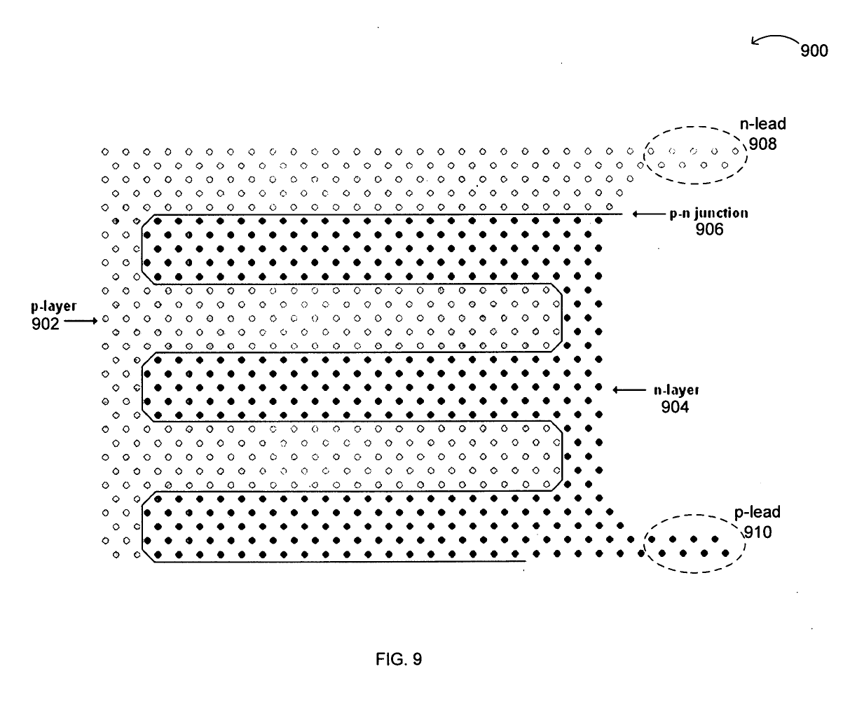

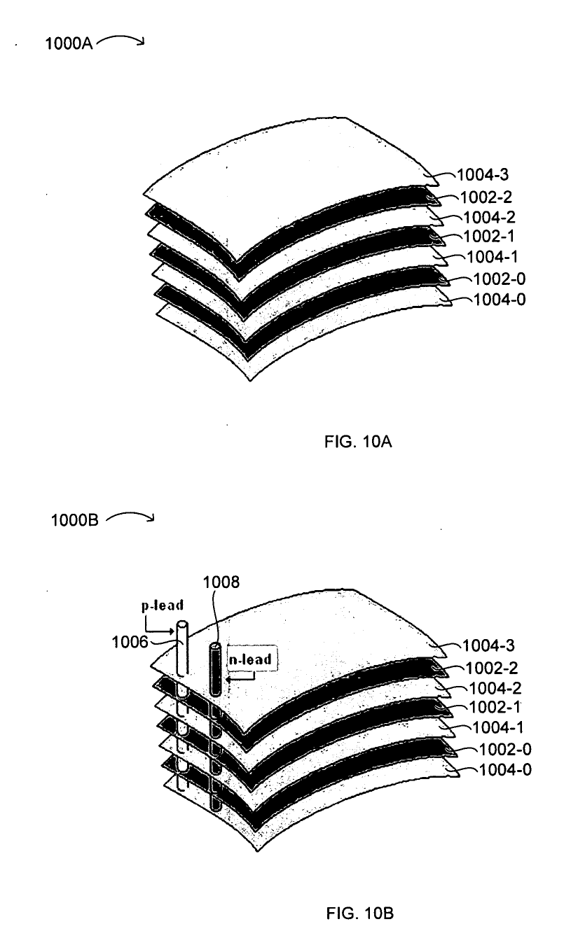

Referring now to FIG. 9, shown is an example 900 of connection busses to bond n-layers and p-layers together. In this example, p-layer 902 and n-layer 904 can form a serpentine shaped p-n junction 906. Alternating layers of p-doped and n-doped diamond can be connected via a “bus” or “rod” connecting structure. Further, n-lead 908 and p-lead 910 can be formed as shown for connections to other circuits and/or components.

Referring now to FIGS. 10A-10B, shown are example non-planar diamond crystalline structures. In FIG. 10A (1000A), non-planar (e.g., curved) layers can be formed using diamond crystalline structures. For example, n-layers 1002-0, 1002-1, and 1002-2, can interleave with p-layers 1004-0, 1004-1, 1004-2, and 1004-3.

In FIG. 10B (1000B), p-lead 1006 and n-lead 1008 can be formed, where p-lead 1006 is connected to each p-layer 1004, and where n-lead 1008 is connected to each n-layer 1002. Although a rod connecting structure is shown here, virtually any shape bus can be utilized, such as during CVD fabrication of layers, in particular embodiments. In any event, n-lead 1008 and p-lead 1006 can form a pair of terminals for connection to other devices.

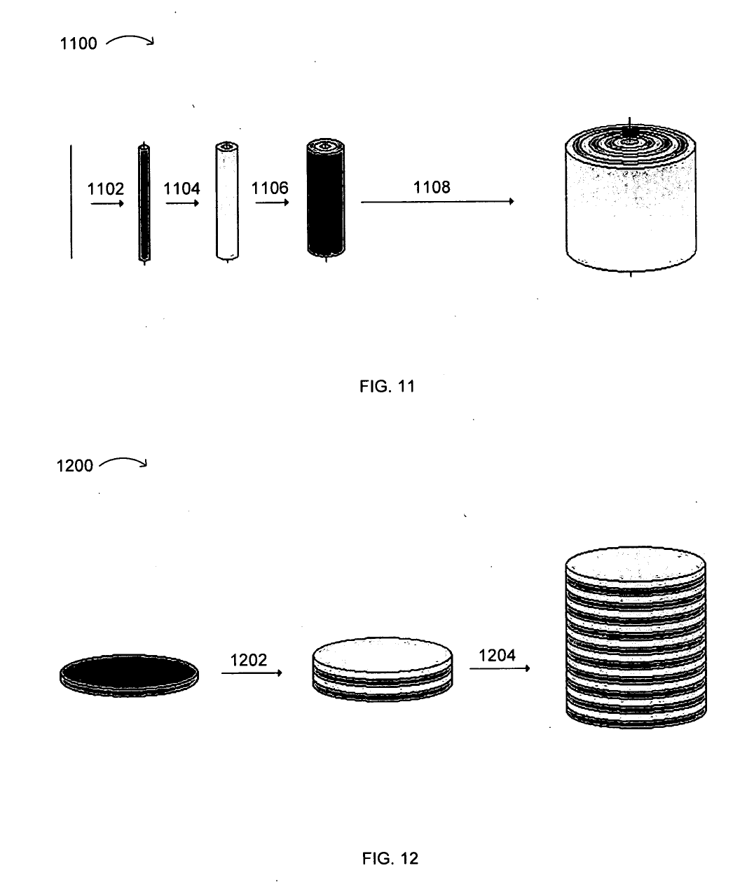

Referring now to FIG. 11, shown is an example 1100 concentric cylinder application of doped diamond. Alternating p-doped and n-doped diamond can be formed and concentric cylinders with a central n-doped rod, followed (1102) by a cylindrical n-doped layer, followed (1104) by a cylindrical p-doped layer, followed (1106) by a cylindrical n-doped layer, and so on, until (1108) a larger alternating doped cylindrical structures formed.

Referring now to FIG. 12, shown is an example 1200 construction of stacked layers in a diamond cylindrical stack structure. A first layer (e.g., n-doped) can be followed (1202) by alternating doped structure (e.g., two n-doped layers alternated with two p-doped layers), followed by (1204) a subsequent larger structure. While the initial CVD target in this particular example is a circle, almost any two-dimensional target shape can be utilized. In this fashion, any shape may be extruded through space, such as a circle being extruded into a cylinder, or an extruded square forming a prismatic shape (e.g., a cube).

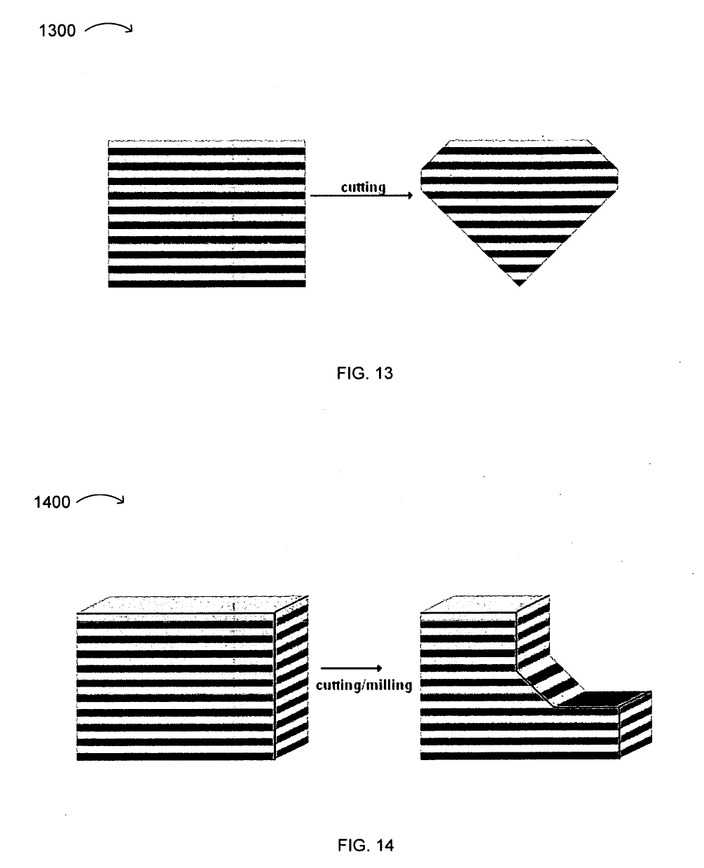

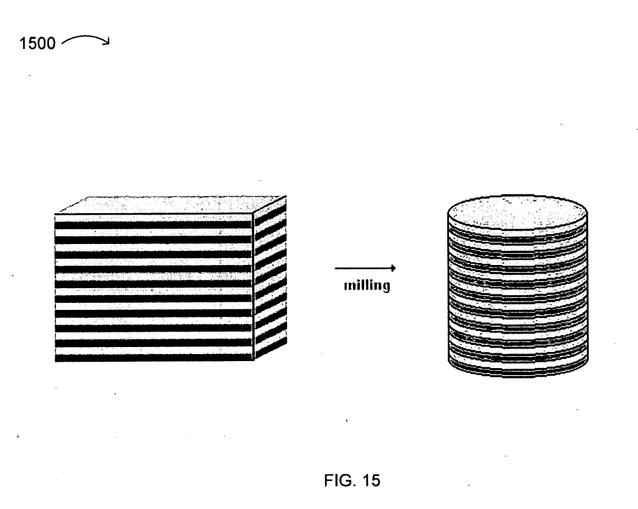

Referring now to FIGS. 13-15, a block of alternating p/n diamond can be cut or milled into almost any shape using existing diamond cutting techniques. Such technology can be employed so that diamond structures in particular embodiments can be shaped to fit any suitable form factor. For example, in FIG. 13, a “gem” shape is formed (1300). In FIG. 14, a prismatic (e.g., for a battery application) shape is formed (1400). In FIG. 15, a cylinder shape is formed (1500).

Although the description has been described with respect to particular embodiments thereof, these particular embodiments are merely illustrative, and not restrictive. For example, any semiconductor device formed using doped diamond layers, as well as possibly intrinsic diamond layers, can be utilized in particular embodiments.

Any suitable programming language can be used to implement the routines of particular embodiments including C, C++, Java, assembly language, etc. Different programming techniques can be employed such as procedural or object oriented. The routines can execute on a single processing device or multiple processors. Although the steps, operations, or computations may be presented in a specific order, this order may be changed in different particular embodiments. In some particular embodiments, multiple steps shown as sequential in this specification can be performed at the same time.

Particular embodiments may be implemented in a computer-readable storage medium for use by or in connection with the instruction execution system, apparatus, system, or device. Particular embodiments can be implemented in the form of control logic in software or hardware or a combination of both. The control logic, when executed by one or more processors, may be operable to perform that which is described in particular embodiments.

Particular embodiments may be implemented by using a programmed general purpose digital computer, by using application specific integrated circuits, programmable logic devices, field programmable gate arrays, optical, chemical, biological, quantum or nanoengineered systems, components and mechanisms may be used. In general, the functions of particular embodiments can be achieved by any means as is known in the art. Distributed, networked systems, components, and/or circuits can be used. Communication, or transfer, of data may be wired, wireless, or by any other means.

It will also be appreciated that one or more of the elements depicted in the drawings/figures can also be implemented in a more separated or integrated manner, or even removed or rendered as inoperable in certain cases, as is useful in accordance with a particular application. It is also within the spirit and scope to implement a program or code that can be stored in a machine-readable medium to permit a computer to perform any of the methods described above.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

Thus, while particular embodiments have been described herein, latitudes of modification, various changes, and substitutions are intended in the foregoing disclosures, and it will be appreciated that in some instances some features of particular embodiments will be employed without a corresponding use of other features without departing from the scope and spirit as set forth. Therefore, many modifications may be made to adapt a particular situation or material to the essential scope and spirit.

What is claimed is:

1. A charge storage device, comprising:
a first node having a plurality of n-type diamond layers connected together; and
a second node having a plurality of p-type diamond layers connected together, the plurality of p-type diamond layers being interleaved with the plurality of n-type diamond layers, wherein each of the plurality of diamond layers is formed using a chemical vapor deposition (CVD).

2. The charge storage device of claim 1, wherein each of the n-type diamond layers has a thickness in a range of from about an atom spacing to greater than about 1 nm.

3. The charge storage device of claim 1, wherein each of the p-type diamond layers has a thickness in a range of from about an atom spacing to greater than about 1 nm.

4. The charge storage device of claim 1, further comprising a dielectric separating the plurality of n-type diamond layers from the plurality of p-type diamond layers, wherein the dielectric comprises intrinsic crystalline diamond.

5. The charge storage device of claim 1, further comprising a bias circuit configured to provide a voltage difference between the first and second nodes.

6. The charge storage device of claim 1, wherein each of the n-type diamond layers include phosphorous dopants.

7. The charge storage device of claim 1, wherein at least one of the diamond layers includes boron dopants.

8. A method of forming a charge storage device, the method comprising:
forming a first node portion from n-type diamond material using chemical vapor deposition (CVD);
forming a second node portion from p-type diamond material using CVD; and
repeating the forming the first node portion and the forming the second node portion for each of a plurality of layers, wherein the plurality of layers are interleaved between the p-type and n-type diamond material.

9. The method of claim 8, further comprising forming a dielectric portion using CVD, the dielectric portion separating the plurality of n-type diamond layers from the plurality of p-type diamond layers.

10. The method of claim 9, wherein the dielectric portion comprises intrinsic crystalline diamond.

11. The method of claim 8, further comprising doping diamond with phosphorous to form the n-type diamond material.

12. The method of claim 8, further comprising doping diamond with boron to form the p-type diamond material.

13. The method of claim 8, further comprising doping diamond with boron to form the n-type and the p-type diamond materials.

14. The method of claim 8, wherein each of the diamond material layers has a thickness in a range of from about an atom spacing to greater than about 1 nm.

15. An apparatus, comprising:
an n-type diamond layer having a plurality of n-doped carbon atoms;
a p-type diamond layer having a plurality of p-doped carbon atoms, wherein each of the n-type diamond layer and the p-type diamond layer have a thickness in a range of from about an atom spacing to greater than about 1 nm, and wherein each of the diamond layers is formed using chemical vapor deposition (CVD);
an n-lead coupled to the n-type diamond layer; and
a p-lead coupled to the p-type diamond layer, wherein each of the n-type diamond layer and the p-type diamond layer conform to a predetermined shape.

16. The apparatus of claim 15, wherein the predetermined shape comprises a circle.

17. The apparatus of claim 15, wherein the predetermined shape comprises a cylinder.

18. The apparatus of claim 15, wherein the predetermined shape comprises a gem-like shape.

19. The apparatus of claim 15, wherein the predetermined shape comprises a shape of an underlying object.

20. The apparatus of claim 15, further comprising a circuit coupled to the n-lead and the p-lead to form a light-emitting diode (LED).
